(19) United States
(12) Patent Application Publication
(10) Pub. No.: US 2026/0081120 A1
(43) Pub. Date: Mar. 19, 2026

(54) TRAP DEVICE AND EXHAUST DEVICE

(71) Applicant: Kioxia Corporation, Tokyo (JP)

(72) Inventor: Takuho YAMADA, Yokkaichi (JP)

(73) Assignee: Kioxia Corporation, Tokyo (JP)

(21) Appl. No.: 19/079,690

(22) Filed: Mar. 14, 2025

(30) Foreign Application Priority Data
Sep. 18, 2024 (JP) 2024-161343

(51) Int. Cl. H01J 37/32

(52) U.S. Cl. CPC H01J 37/32844; H01J 2237/002

(57) ABSTRACT

According to one embodiment, a trap device includes a container that is provided on a way of an exhaust path where exhaust gas supplied from a processing chamber flows and includes a gas inlet to which the exhaust gas is supplied and a gas outlet from which the exhaust gas is discharged. The trap device includes a plurality of cooling fins provided in the container. The plurality of cooling fins has a pair of trap surfaces facing each other. The plurality of cooling fins forms a flow path where the exhaust gas flows between the pair of trap surfaces. The trap device includes a cooling pipe that extends to penetrate the pair of trap surfaces and allows a coolant for cooling the plurality of cooling fins to flow in the cooling pipe.

### CROSS-REFERENCE TO RELATED APPLICATION(S)

This application is based upon and claims the benefit of priority from Japanese Patent Application No. 2024-161343, filed Sep. 18, 2024, the entire contents of which are incorporated herein by reference.

### FIELD

Embodiments described herein relate generally to a trap device and an exhaust device.

### BACKGROUND

In recent years, exhaust devices are known which have a trap device placed on the way of an exhaust path to capture products in exhaust gas supplied from a processing chamber of a semiconductor manufacturing apparatus such as an etching apparatus.

### DESCRIPTION OF THE DRAWINGS

FIG. 1 is a schematic diagram illustrating an example of the configuration of a trap device and an exhaust device according to an embodiment.

FIG. 2 is a schematic diagram illustrating an example of the configuration of the trap device.

FIG. 3 is a schematic diagram illustrating an example of the configuration of the trap device.

FIG. 4 is a schematic diagram illustrating an example of the configuration of the trap device.

FIG. 5 is a schematic diagram illustrating an example in which the trap device captures a product in exhaust gas.

### DETAILED DESCRIPTION

In general, according to one embodiment, a trap device includes a container that is provided on a way of an exhaust path where exhaust gas supplied from a processing chamber flows and includes a gas inlet to which the exhaust gas is supplied and a gas outlet from which the exhaust gas is discharged, a plurality of cooling fins provided in the container, the plurality of cooling fins having a pair of trap surfaces facing each other, the plurality of cooling fins forming a flow path where the exhaust gas flows between the pair of trap surfaces, and a cooling pipe that extends to penetrate the pair of trap surfaces and allows a coolant for cooling the plurality of cooling fins to flow therein.

Hereinafter, embodiments will be described with reference to the drawings. A relation between a thickness and a planar dimension of each element illustrated in the drawings, a ratio of the thickness of each element, and the like may be different from those of an actual product. In addition, in the embodiments, substantially the same elements are denoted by the same reference signs, and descriptions are appropriately omitted.

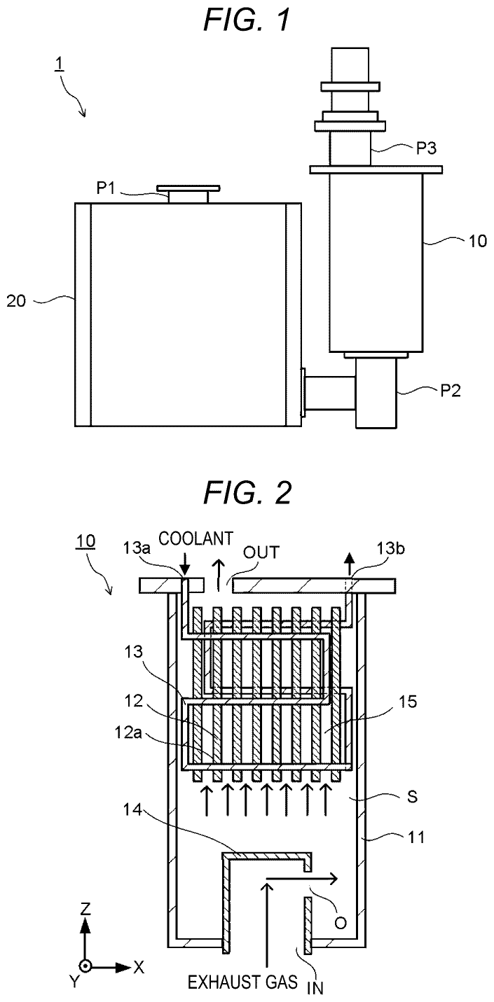

FIG. 1 is a schematic diagram illustrating an example of the configuration of a trap device and an exhaust device according to an embodiment. FIG. 1 illustrates an exhaust device 1.

The exhaust device 1 is configured to discharge exhaust gas from a processing chamber of a semiconductor manufacturing apparatus. The exhaust device 1 includes a trap device 10 and an exhaust pump 20.

Examples of the semiconductor manufacturing apparatus include an etching apparatus. The etching apparatus is configured to, for example, supply predetermined etching gas to the processing chamber to etch a film such as a silicon oxide film and a silicon nitride film using plasma generated from the etching gas. At the time of etching, an unnecessary product is generated and discharged from the processing chamber as exhaust gas. Examples of such an unnecessary product include a carbon compound such as a fluorinated hydrocarbon compound. In order to prevent the product from imposing a burden on the exhaust pump 20 and a detoxifying device, it is preferable that the trap device 10 liquefy or solidify the product in the exhaust gas to capture the resultant.

The trap device 10 is provided on the way of an exhaust path including a pipe P1, a pipe P2, and a pipe P3. The exhaust path allows the exhaust gas to flow therein. The trap device 10 is configured to liquefy or solidify the product in the exhaust gas to capture the resultant. The trap device 10 is installed in the exhaust device 1 such that the exhaust path is formed along the perpendicular direction (vertical direction) of the exhaust device 1.

The exhaust pump 20 is provided on the way of the exhaust path. FIG. 1 illustrates an example in which the exhaust pump 20 is provided at a preceding stage of the trap device 10 on the exhaust path and connected to the trap device 10 via the pipe P2. The present disclosure is not, however, limited thereto, and the exhaust pump 20 may be provided at a subsequent stage of the trap device 10 on the exhaust path. The exhaust pump 20 is, for example, connected to the processing chamber via the pipe P1 and connected to the trap device 10 via the pipe P2. Examples of the exhaust pump 20 include a vacuum pump such as a dry pump. The exhaust pump 20 is configured to discharge exhaust gas from the processing chamber.

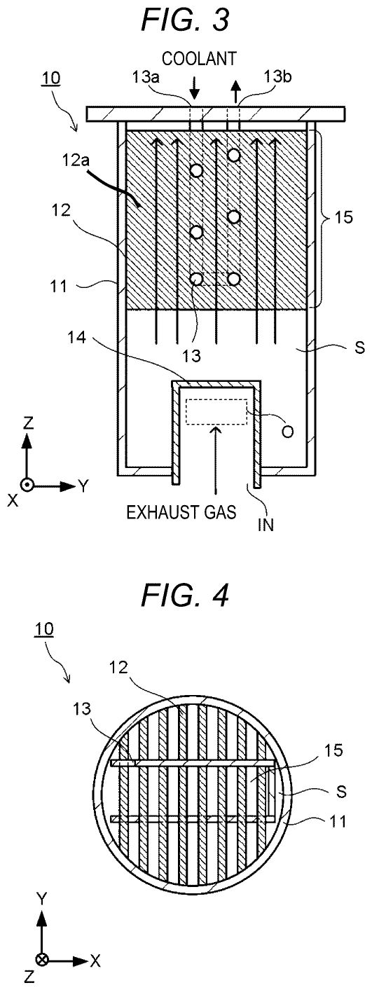

Next, an example of the configuration of the trap device 10 will be described. FIGS. 2, 3, and 4 are schematic diagrams each of which illustrates an example of the configuration of the trap device 10. FIG. 2 schematically illustrates an example of the internal configuration of the trap device 10 as viewed from a Y axis direction. FIG. 3 schematically illustrates an example of the internal configuration of the trap device 10 as viewed from an X axis direction. FIG. 4 schematically illustrates an example of the internal configuration of the trap device 10 as viewed from a Z axis direction. The X axis, the Y axis, and the Z axis vertically intersect. The Z axis corresponds to, for example, the perpendicular direction (vertical direction) of the exhaust device 1. It is noted that the following description of the orientation of the trap device 10 may include some orientation variations based on a device difference when the trap device 10 is installed in the exhaust device 1.

The trap device 10 includes a container 11, a cooling fin 12, a cooling pipe 13, and a cover 14.

The container 11 has a gas inlet IN and a gas outlet OUT. The container 11 has a space S inside where exhaust gas flows from the gas inlet IN to the gas outlet OUT. Examples of the shape of the container 11 include a cylindrical shape. The container 11 extends, for example, in a direction (the Z axis direction, for example) substantially parallel to the perpendicular direction of the exhaust device 1. The container 11 may be formed with a metal material, for example. The metal material may be stainless steel (SUS), for example. An inner surface of the container 11 facing the space S may be subjected to surface treatment for increasing resistance to the exhaust gas.

The gas inlet IN is connected to the pipe P2. The gas inlet IN is provided, for example, on a lower end surface (bottom) of the container 11 in the perpendicular direction, and connected to the space S.

The gas outlet OUT is connected to the detoxifying device via the pipe P3. The exhaust gas that passes through the trap device 10 and is discharged from the gas outlet OUT is processed by the detoxifying device, and is released into the atmosphere, for example. The gas outlet OUT is provided, for example, on an upper end surface (ceiling) of the container 11 in the perpendicular direction, and connected to the space S.

The cooling fin 12 is fixed to an inner wall surface of the container 11 in the space S. The cooling fin 12 has a trap surface 12a. The trap surface 12a extends in the direction substantially parallel to the perpendicular direction of the exhaust device 1. It is preferable that the cooling fin 12 be cooled such that the temperature of the exhaust gas contacting the trap surface 12a is not more than a liquefying temperature of the product in the exhaust gas. The trap surface 12a cooled to not more than the liquefying temperature of the product contacts the exhaust gas supplied from the gas inlet IN, which enables the product in the exhaust gas to be liquefied or solidified. The planar shape of the trap surface 12a is not limited to particular shapes and is, for example, a rectangular shape. In FIGS. 2 to 4, examples of exhaust gas flow directions are indicated by arrows. The plurality of cooling fins 12 is provided which has the trap surfaces 12a extending along the direction substantially parallel to the perpendicular direction of the exhaust device 1 that corresponds to the exhaust gas flow direction. This enables the exhaust gas to be cooled to not more than the liquefying temperature of the product on the trap surface 12a. In FIGS. 2 to 4, the plurality of cooling fins 12 is illustrated. However, the number of cooling fins 12 is not limited to the number of cooling fins 12 illustrated in FIGS. 2 to 4.

The cooling fin 12 may be formed with a metal material, for example. The metal material may be stainless steel (SUS), for example. The cooling fin 12 may be formed using a metal plate to which surface treatment for increasing resistance to the exhaust gas is applied. The cooling fin 12 may be integrally formed with the container 11 using the same material as that of the container 11.

The cooling fins 12 adjacent to each other have a pair of the trap surfaces 12a facing each other. The pair of trap surfaces 12a is placed, for example, at an interval to face each other in a direction (the X axis direction, for example) substantially vertical to the perpendicular direction of the exhaust device 1. The plurality of cooling fins 12 forms a flow path 15 between the pair of trap surfaces 12a. The flow path 15 extends, for example, along the direction substantially parallel to the perpendicular direction of the exhaust device 1. The flow path 15 allows, for example, the exhaust gas from the gas inlet IN to flow toward the upper end surface of the container 11. The pair of trap surfaces 12a may have a length in the Z axis direction that is greater than a length in the X axis direction and a length in the Y axis direction of the pair of trap surfaces 12a.

The cooling pipe 13 is configured to pass a coolant for cooling the cooling fins 12. The coolant may be liquid or gas. The coolant may cool the cooling fins 12 such that the temperature of the exhaust gas contacting the pair of trap surfaces 12a is not more than the liquefying temperature of the product in the exhaust gas. Examples of the coolant include cooling water. For example, the cooling pipe 13 extends to penetrate the pair of trap surfaces 12a in a direction (the X axis direction, for example) intersecting the pair of trap surfaces 12a. In FIG. 3, a part of the cooling pipe 13 is illustrated with a dotted line for the sake of convenience.

The cooling pipe 13 meanders and extends while passing through the plurality of cooling fins 12, so that the cooling pipe 13 penetrates one trap surface 12a at a plurality of parts. For example, the cooling pipe 13 meanders while passing through the plurality of cooling fins 12 forming the flow path 15 and extends in a direction substantially parallel to the flow path 15 (e.g., parallel to the Z axis direction). The cooling pipe 13 may thus extend to intersect in the Y axis direction as illustrated in FIG. 2. The cooling pipe 13 has a coolant inlet 13a and a coolant outlet 13b which are provided, for example, on the upper end surface of the container 11 and connected to a coolant supply source. This enables the coolant to be circulated from the coolant inlet 13a to the coolant outlet 13b of the cooling pipe 13 via the plurality of cooling fins 12. The coolant supply source and the cooling pipe 13 may be connected to each other via a pump for passing the coolant.

The cover 14 is provided between the gas inlet IN and the plurality of cooling fins 12 in the Z axis direction to cover the gas inlet IN. The cover 14 is provided, for example, above the gas inlet IN to overlap the gas inlet IN in the Z axis direction. The cover 14 has an opening O. The opening O serves to connect the gas inlet IN and the space S to each other. This enables the exhaust gas to flow from the gas inlet IN to the space S via the opening O. FIG. 2 illustrates an example in which the opening O is provided in the X axis direction of the cover 14; however, the opening O may be provided in the Y axis direction of the cover 14.

The cover 14 may be formed with a metal material, for example. The metal material may be stainless steel (SUS), for example. A surface of the cover 14 may be subjected to surface treatment in order to increase resistance to the exhaust gas. The shape of the cover 14 is not limited to particular shapes, and any other shape that allows the gas inlet IN to be covered may be used. Examples of the shape of the cover 14 include prismatic, pyramidal, cylindrical, conical, dome-shaped, hemispherical, and partially spherical.

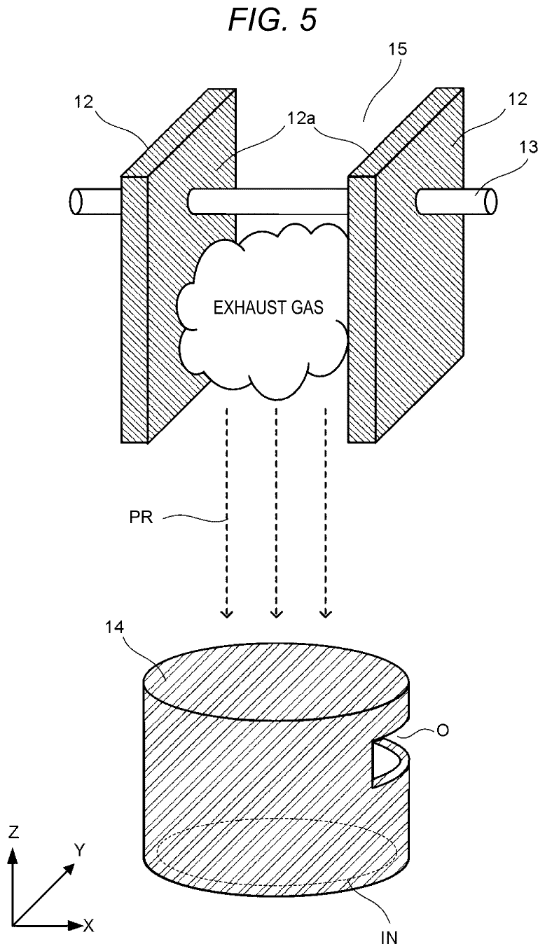

Next, a description is given of an example in which the trap device 10 captures a product in exhaust gas. FIG. 5 is a schematic diagram illustrating an example in which the trap device 10 captures a product in exhaust gas. FIG. 5 schematically illustrates a pair of the trap surfaces 12a, the cooling pipe 13, and the cover 14.

In the present embodiment, the trap device 10 includes the plurality of cooling fins 12 having the pair of trap surfaces 12a forming the flow path 15 in which exhaust gas flows in the direction substantially parallel to the perpendicular direction of the exhaust device 1. This increases an area cooled by the plurality of cooling fins 12 without significantly lowering the conductance of the exhaust gas in the container 11 of the trap device 10 to thereby cool the exhaust gas efficiently, for example as compared with a case where the plurality of cooling fins 12 is placed such that the pair of trap surfaces 12a forms the flow path 15 in the direction substantially vertical to the perpendicular direction of the exhaust device 1.

Exhaust gas supplied from the gas inlet IN, which is provided below the cooling fins 12, to the space S flows through the flow path 15 along the direction substantially parallel to the perpendicular direction of the exhaust device 1, and is discharged from the gas outlet OUT, which is provided above the cooling fins 12. At this time, if the exhaust gas supplied from the gas inlet IN has a temperature higher than a liquefying temperature of the product PR for example, then the product PR in the exhaust gas remains in a gaseous state without being liquefied/solidified and is discharged from the trap device 10 as is. This allows, for example, the product PR to attach to the pipe P3 at the subsequent stage of the trap device 10, which causes a blockage in the exhaust path. The blockage in the pipe P3 sometimes, for example, causes a pressure sensor, which is provided at the subsequent stage of the trap device 10 in the exhaust path, to operate, which stops the exhaust pump 20 in some cases.

In view of this, in the present embodiment, the cooling pipe 13 extends to penetrate the pair of trap surfaces 12a, and the plurality of cooling fins 12 is cooled such that the pair of trap surfaces 12a is not more than the liquefying temperature of the product PR. This enables the exhaust gas to be cooled to not more than the liquefying temperature of the product PR on the trap surface 12a. Further, variations in the cooling temperature in the trap surface 12a can be reduced, which prevents reduction in cooling efficiency of the cooling fins 12. If the cooling pipe 13 extends around a region including the plurality of cooling fins 12 without penetrating the pair of trap surfaces 12a, variations in cooling temperature occur, for example, between the center part and an edge of the trap surface 12a, which sometimes reduces the cooling efficiency of the cooling fins 12. In contrast, according to the plurality of cooling fins 12 having the pair of trap surfaces 12a into which the cooling pipe 13 is penetrated, the product PR in the exhaust gas is stably cooled to not more than the liquefying temperature of the product PR. This enables the product PR to be liquefied or solidified and to be captured on the trap surface 12a. As a result, a blockage of the exhaust path can be prevented.

The temperature of the exhaust gas contacting the trap surface 12a is cooled to not more than the liquefying temperature of the product PR in the exhaust gas, and thus the product PR is liquefied or solidified and is captured. Thereafter, the product PR falls under the plurality of cooling fins 12 along a direction parallel to the perpendicular direction of the exhaust device 1.

The gas inlet IN is covered with the cover 14 in the perpendicular direction of the container 11, which prevents the liquefied or solidified product PR from flowing backwards in the exhaust path from the gas inlet IN. As a result, a blockage of the exhaust path by the product PR can be prevented. The liquefied or solidified product PR is accumulated on an inner bottom surface of the container 11, which enables efficient collection of the product PR by detaching the pipe P2 from the container 11, for example. Further, the product PR is let fall from the trap surfaces 12a of the plurality of cooling fins 12 extending in the direction substantially parallel to the perpendicular direction and the product PR can be captured at one location of the container 11. This simplifies cleaning of the container 11 and facilitates maintenance of the trap device 10.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A trap device comprising:
a container provided on a way of an exhaust path where an exhaust gas supplied from a processing chamber flows, the container including a gas inlet to which the exhaust gas is supplied and a gas outlet from which the exhaust gas is discharged;
a plurality of cooling fins provided in the container, the plurality of cooling fins having a pair of trap surfaces facing each other, the plurality of cooling fins forming a flow path in a first direction where the exhaust gas flows between the pair of trap surfaces; and
a cooling pipe that extends to penetrate the pair of trap surfaces and allows a coolant for cooling the plurality of cooling fins to flow in the cooling pipe.

2. The trap device according to claim 1, further comprising
a cover that covers the gas inlet and is provided between the gas inlet and the plurality of cooling fins.

3. The trap device according to claim 1, wherein
the plurality of cooling fins includes a metal material.

4. The trap device according to claim 1, wherein
the plurality of cooling fins is positioned closer to the gas outlet than to the gas inlet in the container.

5. The trap device according to claim 1, wherein
the cooling pipe meanders while passing through the plurality of cooling fins forming the flow path and extends in a direction substantially parallel to the first direction.

6. The trap device according to claim 5, wherein
the cooling pipe penetrates each trap surface of the plurality of cooling fins at a plurality of parts in a direction substantially perpendicular to the first direction.

7. The trap device according to claim 1, wherein
a length of the pair of trap surfaces in a direction substantially parallel to the first direction is greater than a length of the pair of trap surfaces in a direction substantially perpendicular to the first direction.

8. A trap device comprising:
a container provided on a way of an exhaust path where an exhaust gas supplied from a processing chamber flows, the container including a gas inlet to which the exhaust gas is supplied and a gas outlet from which the exhaust gas is discharged;
a plurality of cooling fins provided in the container, the plurality of cooling fins having a pair of trap surfaces facing each other, the plurality of cooling fins forming a flow path in a first direction where the exhaust gas flows between the pair of trap surfaces;
a cooling pipe where a coolant for cooling the plurality of cooling fins flows; and
a cover that covers the gas inlet and is provided between the gas inlet and the plurality of cooling fins.

9. The trap device according to claim 8, wherein
the plurality of cooling fins includes a metal material.

10. The trap device according to claim 8, wherein
the plurality of cooling fins is positioned closer to the gas outlet than to the gas inlet in the container.

11. The trap device according to claim 8, wherein
a length of the pair of trap surfaces in a direction substantially parallel to the first direction is greater than a length of the pair of trap surfaces in a direction substantially perpendicular to the first direction.

12. The trap device according to claim 8, wherein
the cover includes a metal material.

13. An exhaust device comprising:
a trap device including
a container provided, on a way of an exhaust path where an exhaust gas supplied from a processing chamber flows, to extend in a direction substantially parallel to a vertical direction of the exhaust device, the container including a gas inlet to which the exhaust gas is supplied and a gas outlet from which the exhaust gas is discharged,
a plurality of cooling fins provided in the container, the plurality of cooling fins having a pair of trap surfaces extending in a direction substantially parallel to the vertical direction of the exhaust device and facing each other in a direction substantially perpendicular to the vertical direction of the exhaust device, the plurality of cooling fins forming a flow path where the exhaust gas flows between the pair of trap surfaces, and
a cover that covers the gas inlet and is provided between the gas inlet and the plurality of cooling fins in the vertical direction of the exhaust device; and
an exhaust pump provided at a preceding stage or a subsequent stage of the trap device on the exhaust path.

14. The exhaust device according to claim 13, wherein the plurality of cooling fins includes a metal material.

15. The exhaust device according to claim 13, wherein
the plurality of cooling fins is positioned closer to the gas outlet than to the gas inlet in the container.

16. The exhaust device according to claim 13, wherein
the trap device further includes a cooling pipe that extends to penetrate the pair of trap surfaces and allows a coolant for cooling the plurality of cooling fins to flow in the cooling pipe.

17. The exhaust device according to claim 16, wherein
the cooling pipe meanders while passing through the plurality of cooling fins and extends in a direction substantially parallel to the vertical direction of the exhaust device.

18. The exhaust device according to claim 17, wherein
the cooling pipe penetrates each trap surface of the plurality of cooling fins at a plurality of parts in a direction substantially perpendicular to the vertical direction of the exhaust device.

19. The exhaust device according to claim 13, wherein
a length of the pair of trap surfaces in the direction substantially parallel to the vertical direction of the exhaust device is greater than a length of the pair of trap surfaces in a direction substantially perpendicular to the vertical direction of the exhaust device.

20. The exhaust device according to claim 13, wherein
the cover has an opening in a direction substantially perpendicular to the vertical direction of the exhaust device.
